(19) United States
(12) Patent Application Publication
(10) Pub. No.: US 2023/0326394 A1
(43) Pub. Date: Oct. 12, 2023

(54) DISPLAY PANEL AND DISPLAY APPARATUS

(71) Applicant: Shanghai Tianma Micro-Electronics Co., Ltd., Shanghai (CN)

(72) Inventors: Tenggang Lou, Shanghai (CN); Nanfeng Cheng, Shanghai (CN)

(73) Assignee: Shanghai Tianma Micro-Electronics Co., Ltd., Shanghai (CN)

(21) Appl. No.: 17/932,009

(22) Filed: Sep. 14, 2022

(30) Foreign Application Priority Data
Jun. 29, 2022 (CN) 202210760505.2

(51) Int. Cl. G09G 3/32; G11C 19/28

(52) U.S. Cl. CPC G09G 3/32; G09G 2310/0286; G11C 19/28

(57) ABSTRACT

A display panel including a display area, subpixels located in the display area, and a shift register. The shift register includes a plurality of stages of shift units that is cascaded. Each of the plurality of stages of shift units is electrically connected to one of control signal lines and at least two of the subpixels respectively, and is configured to output a driving signal to the at least two of the subpixels in response to a control signal. The shift register is located in the display area, and at least one of the control signal lines is located in the display area.

### CROSS-REFERENCE TO RELATED APPLICATIONS

The present application claims priority to Chinese Patent Application No. 202210760505.2, filed on Jun. 29, 2022, the content of which is incorporated herein by reference in its entirety.

### TECHNICAL FIELD

The disclosure relates to a technical field of displaying, in particular to a display panel and a display apparatus.

### BACKGROUND

Light-emitting Diode (LED) display panels are widely used in various electronic devices due to their advantages of self-illumination, low driving voltage, high luminous efficiency, short response time, high definition and contrast.

In recent years, narrow bezel designs of display panels have developed as a trend. Accordingly, there is an urgent need to better realize a narrow bezel or even a bezel-less design of an LED display panel.

### SUMMARY

In view of this, a display panel and a display apparatus are provided in embodiments of the disclosure, which can optimize a wiring design while effectively realizing an ultra-narrow bezel or bezel-less display panel.

In an aspect, a display panel is provided in an embodiment of the present disclosure, which includes a display area, subpixels, and a shift register. The subpixels are located in the display area.

The shift register may include a plurality of stages of shift units that is cascaded, each of the plurality of stages of shift units is electrically connected to control signal lines and at least two of the subpixels respectively, and is configured to output a driving signal to at least two of the subpixels in response to a control signal. The shift register may be located in the display area, and at least one control signal line of the control signal lines is located in the display area.

In another aspect, a display apparatus is provided in an embodiment of the present disclosure, which includes the display panel described above. The technical solutions described herein have multiple beneficial effects, as described herein.

In some embodiments of the disclosure, by arranging the shift register and at least one control signal line electrically connected to the shift register in the display area, on the one hand, the shift register and this part of control signal lines can be prevented from consuming left and right frame space, which is more conducive to realize the ultra-narrow bezel design of the display panel, especially when all of the control signal lines are located in the display area, and a bezel-less design of the display panel can be further realized.

On the other hand, if the shift register is provided in the display area and the control signal line is provided in a frame area, the control signal line may be electrically connected to the shift register through a connecting line extending from the frame area to the display area. In such embodiments, a length of the connecting line is large, which not only results in overlapping with other signal lines in the display area, such as data lines, resulting in large coupling capacitance, but also results in large delay and attenuation of the control signal in transmission. According to one embodiment of the disclosure, at least one control signal line is also arranged in the display area, so that a length of a connecting line between the at least one control signal line and the shift register can be greatly reduced, thereby effectively reducing coupling of the connecting line in the display area, reducing the delay and attenuation of the control signal in transmission, effectively improving operating reliability of the shift register, further improving accuracy of a driving signal received by the subpixel and optimizing display performance of the display panel.

### BRIEF DESCRIPTION OF DRAWINGS

In order to explain technical schemes of the embodiments of the present disclosure more clearly, the drawings used in the embodiments will be briefly introduced below. Obviously, the drawings in the following description are merely intended to be some of the embodiments of the present disclosure, and other drawings can be obtained for those of ordinary skill in the art according to these drawings without paying creative efforts.

FIG. 1 is a structural schematic diagram of a display panel according to an embodiment of the present disclosure;

FIG. 2 is a schematic diagram of an arranging position of a shift unit according to an embodiment of the present disclosure;

FIG. 3 is a schematic diagram of an arranging position of a control signal line according to an embodiment of the present disclosure;

FIG. 4 is a schematic diagram of a circuit structure of a shift unit according to an embodiment of the present disclosure;

FIG. 5 is a structural schematic diagram of a control signal line according to an embodiment of the present disclosure;

FIG. 6 is another structural schematic diagram of a control signal line according to an embodiment of the present disclosure;

FIG. 7 is yet another structural schematic diagram of a control signal line according to an embodiment of the present disclosure;

FIG. 8 is a schematic diagram of a film structure according to an embodiment of the present disclosure;

FIG. 9 is a schematic diagram of another arranging position of a control signal line according to an embodiment of the present disclosure;

FIG. 10 is a schematic diagram of another arranging position of a control signal line according to an embodiment of the present disclosure;

FIG. 11 is a schematic diagram of another arranging position of a control signal line according to an embodiment of the present disclosure;

FIG. 12 is a schematic diagram of another arranging position of a control signal line according to an embodiment of the present disclosure;

FIG. 13 is a schematic diagram of an arrangement of subunits in a shift unit according to an embodiment of the present disclosure;

FIG. 14 is a schematic diagram of another arrangement of subunits in a shift unit according to an embodiment of the present disclosure;

FIG. 15 is a schematic view of another film structure of a display panel according to an embodiment of the present disclosure;

FIG. 16 is a schematic view of still another film structure of a display panel according to an embodiment of the present disclosure;

FIG. 17 is a structural diagram of a data line according to an embodiment of the present disclosure;

FIG. 18 is a structural diagram of a shift register according to an embodiment of the present disclosure;

FIG. 19 is another structural diagram of a shift register according to an embodiment of the present disclosure; and

FIG. 20 is a schematic structural diagram of a display apparatus according to an embodiment of the present disclosure.

### DESCRIPTION OF EMBODIMENTS

In order to better understand technical schemes of the present disclosure, embodiments of the present disclosure will be described in detail below with reference to the drawings.

It should be clear that described embodiments are only part of the embodiments of the present disclosure, but not all of them. On a basis of the embodiments in this disclosure, all other embodiments obtained by the ordinary skilled in the art without paying creative effort are within a protection scope of this disclosure.

Terms used in the embodiments of the present disclosure are only for the purpose of describing specific embodiments, but not intended to limit the present disclosure. Singular forms of “a”, “said” and “the” used in the embodiments of the present disclosure and the appended claims are also intended to include a plural form, unless the context clearly indicates other meaning otherwise.

It should be understood that a term “and/or” used in this document is only a kind of association relationship to describe associated objects, which means that there can be three kinds of relationships, for example, A and/or B, which can indicate only A, A and B, and only

B. In addition, a character “/”in this document generally indicates that associated object are in an “or” relationship.

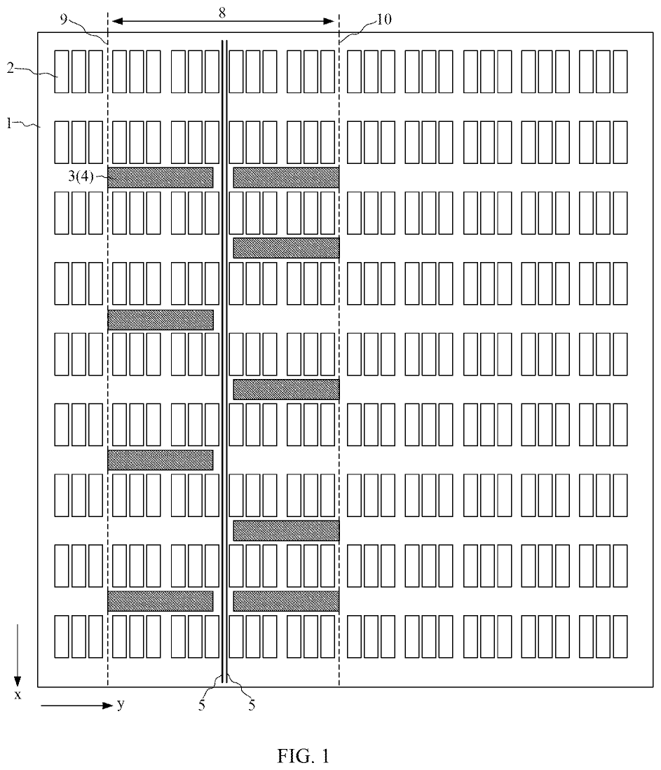

A display panel is provided in an embodiment of the present disclosure. FIG. 1 is a structural schematic diagram of the display panel according to an embodiment of the present disclosure. A shown in FIG. 1, the display panel may have a display area 1 and include subpixels 2 and a shift register 3. The subpixels 2 are located in the display area 1, and the shift register 3 includes a plurality of stages of shift units 4 that is cascaded. Each of the plurality of stages of shift units 4 is electrically connected to a control signal line 5 and at least two of the subpixels 2 respectively and is configured to output a driving signal to at least two of the subpixel 2 in response to a control signal provided by the control signal line 5, the driving signal can be a scanning signal or a light-emitting signal. The shift register 3 is located in the display area 1, and at least one control signal line 5 is located in the display area 1.

It should be noted that the subpixels 2 may each include a pixel circuit and a light-emitting diode which are electrically connected to each other, and the shift unit 4 is electrically connected to the pixel circuit in the subpixel 2, and the plurality of stages of shift units 4 sequentially outputs driving signals to pixel circuits which are electrically connected to the shift units 4, so that the pixel circuit controls the light-emitting diodes to emit light under action of the driving signals.

In embodiments of the disclosure, by arranging the shift register 3 and at least one control signal line 5 electrically connected to the shift register 3 in the display area 1, on the one hand, the shift register 3 and the at least one control signal line 5 can be prevented from consuming left and right frame space, which is more conducive to realize the ultra-narrow bezel design of the display panel, especially when all of the control signal lines 5 are located in the display area 1, and a bezel-less design of the display panel can be further realized.

On the other hand, if the shift register 3 is provided in the display area 1 and the control signal line 5 is provided in a frame area, the control signal line 5 may be electrically connected to the shift register 3 through a connecting line extending from the frame area to the display area 1. At this time, the length of the connecting line is large, the connecting line not only overlaps with other signal lines in the display area 1, such as data lines, resulting in large coupling capacitance, but also results in large delay and attenuation of the control signal in transmission. According to the embodiment of the disclosure, at least one control signal line 5 is also arranged in the display area 1, so that a length of the connecting line between the at least one control signal line 5 and the shift register 3 can be greatly reduced, thereby effectively reducing coupling of the connecting line in the display area 1, reducing the delay and attenuation of the control signal in transmission, effectively improving operating reliability of the shift register 3, further improving accuracy of a driving signal received by the subpixel 2 and optimizing display performance of the display panel.

In some embodiments, referring to FIG. 1 again, the display area 1 includes a register arranging area 8, the shift register 3 is located in the register arranging area 8, and the at least one control signal line 5 is also located in the register arranging area 8.

It should be noted that the register arranging area 8 in the embodiment of the present disclosure can be defined by a boundary of the shift register 3. For example, referring to FIG. 1, the shift register 3 includes a first side and a second side facing each other in a second direction y, and the register arranging area 8 includes a first edge 9 and a second edge 10 facing each other in the second direction y. The first edge 9 coincides with a boundary of the shift register 3 on the first side, and the second edge 10 coincides with a boundary of the shift register 3 on the second side.

In an embodiment of the present disclosure, by further arranging the at least one control signal line 5 in the register arranging area 8, a length of the connecting line between the at least one control signal line 5 and the shift register 3 is shorter, so that coupling of the connecting line in the display area and the delay and attenuation of the control signal can be reduced more greatly.

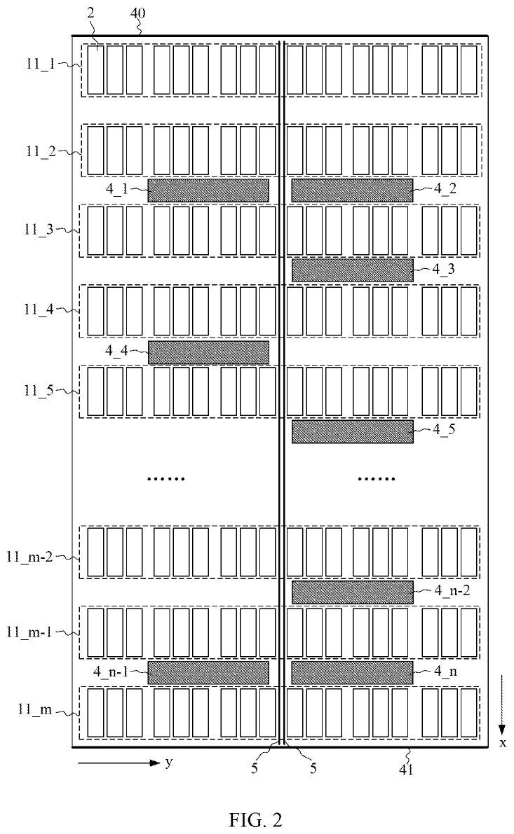

FIG. 2 is a schematic diagram of an arranging position of the shift unit 4 according to an embodiment of the present disclosure. In a possible implementation, as shown in FIG. 2, the display panel further includes a plurality of pixel rows 11 arranged along a first direction x, and each of the plurality of pixel rows 11 includes at least two of the subpixels 2 arranged along a second direction y, and the first direction x intersects with the second direction y.

In some embodiments, the shift unit 4 is located between two adjacent pixel rows 11, and both a first stage of shift unit 4_1 and a second stage of shift unit 4_2 are located between a second pixel row 11_2 and a third pixel row 11_3. The display panel includes a first panel edge 40 extending in the second direction y, the first pixel row 11_1 is adjacent to the first panel edge 40, the second pixel row 11_2 is located at a side of the first pixel row 11_1 away from the first panel edge 40, the third pixel row 11_3 is located at a side of the second pixel row 11_2 away from the first panel edge 40, and the second stage of shift unit 4_2 is electrically connected to the subpixel 2 in the second pixel row 11_2. For clarity, in FIG. 2, an i-th pixel row is denoted by a reference numeral 11_i, and an i-th stage of shift unit is denoted by a reference numeral 4_i.

In the above structure, by arranging the shift unit 4 in an interval between two adjacent pixel rows 11, the arranging space of the shift unit 4 and the arranging space of the subpixel 2 are independent from each other, so that the shift unit 4 does not disturb an original arrangement of the subpixel 2, and mutual interference between the subpixel 2 and metal wirings in the shift unit 4 can be reduced. In some embodiment, by arranging the first stage of shift unit 4_1 and the second stage of shift unit 4_2 between the second pixel row 11_2 and the third pixel row 11_3, it is possible to prevent the shift unit 4 from consuming a space between the first pixel row 11_1 and the second pixel row 11_2, so that this space can be used for accommodating other circuit structures in the display panel, such as electro-static discharge circuits, which facilitates reducing of a distance between the first pixel row 11_1 and the first panel edge 40, and a black edge at the first panel edge 40 can be avoided.

In some embodiments, referring to FIG. 2 again, the display panel further includes a second panel edge 41 opposite to the first panel edge 40. The display panel includes m pixel rows 11, and the shift register 3 includes n stages of shift units shift units 4, where n may be equal to m or m+1. A n-1-th stage of shift unit 4_n-1 and an n-th stage of shift unit 4_n are both located on a side of a m-th pixel row 11_m toward a m-1-th pixel row 11_m-1, for example, are both located between the m-1-th pixel row 11_m-1 and the m-th pixel row 11_m, thus further preventing the shift unit 4 from consuming the space between the m-th pixel row 11_m and the second panel edge 41, facilitating reducing of a distance between the m-th pixel row 11_m and the second panel edge 41, and preventing black edges visually appearing at the second panel edge 41.

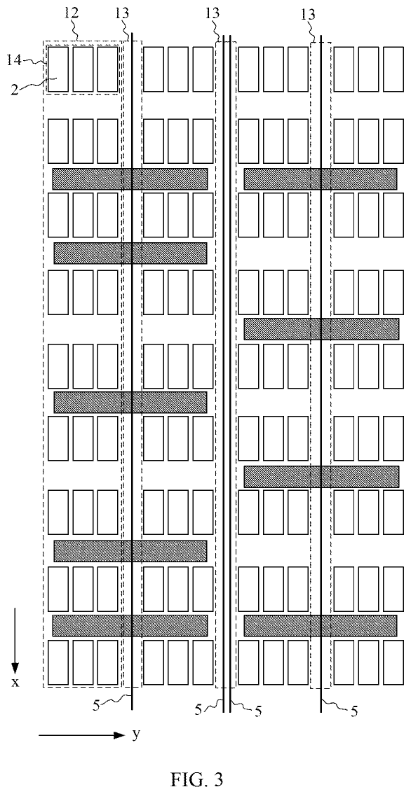

In an embodiment, as shown in FIG. 3, which is a schematic diagram of an arranging position of the control signal line 5 according to an embodiment of the present disclosure, the display panel includes pixel columns 12 and spacing areas 13 that are alternately arranged along the second direction y. The pixel column 12 includes a plurality of pixels 14 arranged along the first direction x, and each of the plurality of pixels 14 includes at least two the subpixels 2, and the first direction x intersects with the second direction y. At least one control signal line 5 is located in the spacing area 13. It should be noted that, in the embodiment of the present disclosure, the pixel 14 may include a red subpixel, a green subpixel and a blue subpixel, or may also include a red subpixel, a green subpixel, a blue subpixel and a white subpixel. A color, a number and an arrangement of subpixels included in the pixel 14 are not specifically limited in embodiments of the present disclosure.

In existing layout designs, multiple subpixels 2 in a same pixel 14 are arranged compactly, so that a distance between two adjacent subpixels 2 in the second direction y is small, while a distance between two adjacent pixels 14 in the second direction y is relatively large. That is, a width of the spacing area 13 between two adjacent pixel columns 12 is significantly larger than a spacing between two adjacent columns of subpixels 2 in a same pixel column 12.

If the control signal line 5 is arranged between the two adjacent columns of subpixels 2 in the same pixel column 12, an arrangement of the control signal line 5 and the data line may be very compact, resulting in large coupling capacitance between the control signal line 5 and the data line. According to the embodiment of the present disclosure, the control signal line 5 is arranged in the spacing area 13 between the pixel columns 12, on the one hand, there is a large arranging space for the control signal line 5, so that the distance between the control signal line 5 and the data line can be widened so as to reduce coupling between this part of signal lines and mutual influence between signals; and on the other hand, a line width of the control signal line 5 can be increased to a certain extent, so as to reduce a load of the control signal line 5, thereby reducing voltage drop of the control signal in transmission to a greater extent.

In the present disclosure, a circuit structure and an operating principle of the shift unit 4 are illustrated firstly before describing a specific structure of the control signal line 5.

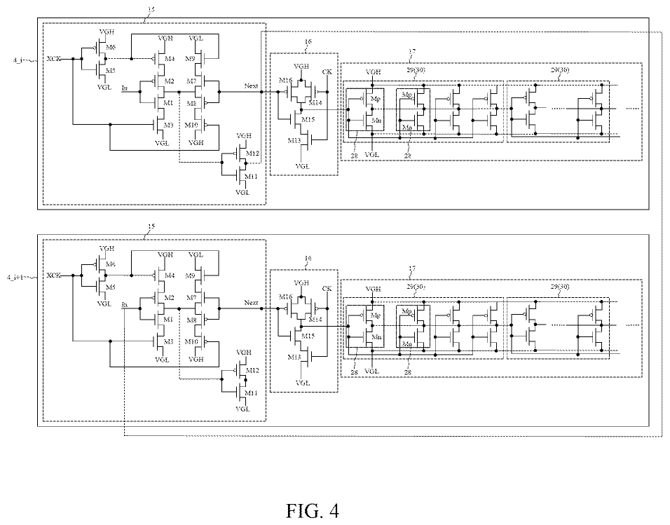

As shown in FIG. 4, which is a schematic diagram of a circuit structure of the shift unit 4 according to an embodiment of the present disclosure, the shift unit 4 includes a latch module (latch) 15, a logic module (nand) 16 and a buffer module (buffer) 17. The logic module 16 is electrically connected between the latch module 15 and the buffer module 17, and the buffer module 17 is electrically connected between the logic module 16 and the subpixel 2.

The latch module 15 includes a shift control terminal In and a shift output terminal Next, and a shift output terminal Next of a latch module 15 in an i-th stage of shift unit 4_i is electrically connected to a shift control terminal In of a latch module 15 in the i+1-th stage of shift unit 4_i+1 to realize a sequential shift function.

In some embodiments, the latch module 15 includes a first clock signal terminal XCK, and is configured to output a shift control signal to the shift output terminal Next in response to a signal received by the first clock signal terminal XCK and a signal received by the shift control terminal In. In some embodiments, the logic module 16 includes a second clock signal terminal CK, and the logic module 16 is configured to output a signal to the buffer module 17 in response to a signal received by the second clock signal terminal CK and the shift control signal transmitted by the latch module 15.

In order to realize normal operations of the shift register 3, in the shift register 3, the first clock signal terminal XCK of the latch module 15 in an odd-numbered stage of shift unit 4 (first stage of shift unit 4_1, third stage of shift unit 4_3, fifth stage of shift unit 4_5, etc. . . . ) receives a same clock signal as the second clock signal terminal CK of the logic module 16 in an even-numbered stage of shift units 4 (second stage of shift unit 4_2, fourth stage of shift unit 4_4, sixth stage of shift unit 4_6, etc . . . ), and the second clock signal terminal CK of the logic module 16 in the odd-numbered stage of shift unit 4 receives a same clock signal as the first clock signal terminal XCK of the latch module 15 in the even-numbered stage of shift unit 4.

In a circuit structure, referring to FIG. 4, the latch module 15 may specifically include a first transistor MI through a twelfth transistor M12, and the logic module 16 may specifically include a thirteenth transistor M13 through a sixteenth transistor M16. A connection mode of the above transistors is the same as that of the related art, which will not be repeatedly described in detail here again.

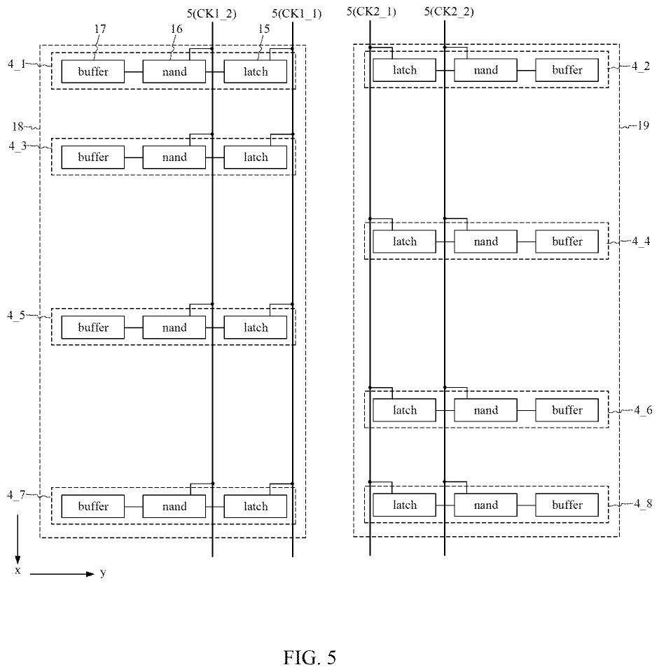

In a possible implementation, as shown in FIG. 5, which is a schematic diagram of the structure of the control signal line 5 according to an embodiment of the present disclosure, in the shift register 3, a part of shift units 4 are arranged along the first direction x to form a first unit column 18, and another part of shift units 4 are arranged along the first direction x to form a second unit column 19. The first unit column 18 and the second unit column 19 are arranged along the second direction y, and the first direction x intersects with the second direction y.

The control signal line 5 includes a first positive clock line CK1_1, a first negative clock line CK1_2, a second positive clock line CK2_1 and a second negative clock line CK2_2. At a same moment, signals provided by the first positive clock line CK1_1 and the second positive clock line CK2_1 are the same, and signals provided by the first negative clock line CK2_1 and the second negative clock line CK2_2 are the same. That is, the first positive clock line CK1_1 and the first negative clock line CK2_1 can be regarded as a set of clock signal lines, and the second positive clock line CK2_1 and the second negative clock line CK2_2 can be regarded as another set of clock signal lines.

The shift unit 4 in the first unit column 18 is electrically connected to the first positive clock line CK1_1 and the first negative clock line CK2_1, and the shift unit 4 in the second unit column 19 is electrically connected to the second positive clock line CK2_1 and the second negative clock line CK2_2.

Combined with above description of respective modules in the shift unit 4, the first positive clock line CK1_1 and the first negative clock line CK2_1 being connected to the shift unit 4 in the first unit column 18 described above specifically means that in the first unit column 18, the first clock signal terminal XCK of the latch module 15 and the second clock signal terminal CK of the logic module 16 are electrically connected to the set of clock signal lines, namely the first positive clock line CK1_1 and the first negative clock line CK2_1.

When the first unit column 18 includes only the odd-numbered stages of shift units 4 or the even-numbered stages of shift units 4, the latch module 15 in the first unit column 18 is electrically connected to the first positive clock line CK1_1 and the logic module 16 is electrically connected to the first negative clock line CK2_1. When the first unit column 18 includes both the odd-numbered stages of shift units 4 and even-numbered stages of shift units 4, the latch module 15 in odd-numbered stage of shift unit 4 is electrically connected to the first positive clock line CK1_1, the logic module 16 in odd-numbered stage of shift unit 4 is electrically connected to the first negative clock line CK2_1, and the latch module 15 in even-numbered stage of shift unit 4 is electrically connected to the first negative clock line CK2_1, and the logic module 16 in odd-numbered stage of shift units 4 is electrically connected to the first positive clock line CK1_1. Therefore, it can be realized that the latch module 15 in the odd-numbered stage of shift unit 4 receives a same clock signal as the logic module 16 in the even-numbered stage of shift unit 4, and the logic module 16 in the odd-numbered stage of shift unit 4 receives a same clock signal as the latch module 15 in the even-numbered stage of shift unit 4. This also applies to the second unit column 19, which will not be repeatedly described here again.

In one embodiment of the present disclosure, by providing an individual set of clock signal lines for a respective unit column, a wiring design between the latch module 15 and the logic module 16 in the unit column and the clock signal line can be optimized. For example, by arranging the set of clock signal lines (including the first positive clock line CK1_1 and the first negative clock line CK2_1) in an area where the first unit column 18 is located, lengths of the connecting wirings between this set of clock lines and respective shift units 4 in the first unit column 18 can be reduced. Similarly, by arranging a set of clock signal lines (including t the second positive clock line CK2_1 and the second negative clock line CK2_2) in an area where the second unit column 19 is located, lengths of the connecting wirings between this set of the clock signal lines and respective shift units 4 in the second unit column 19 can be reduced, thereby effectively reducing coupling between these connecting wirings and other signal lines, and reducing the delay and attenuation of the clock signal in transmission.

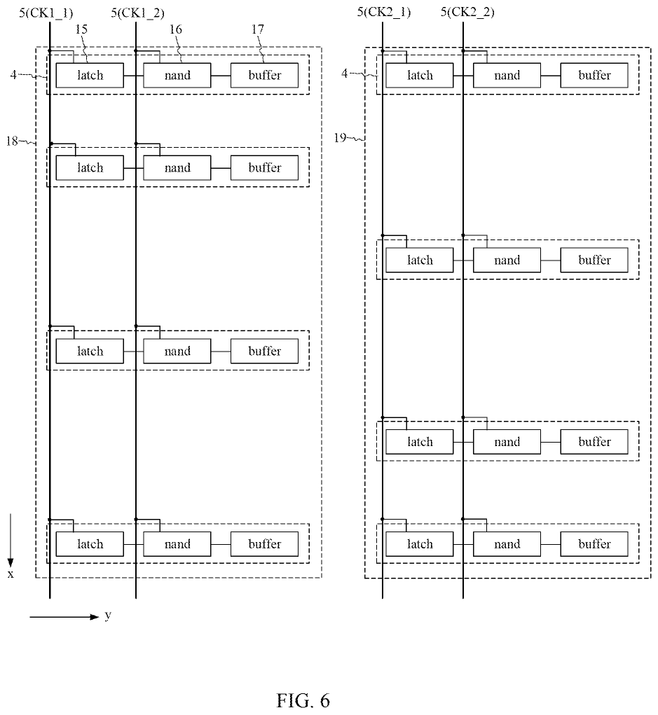

In addition, with the additional set of clock signal, an arrangement of respective modules of the shift units 4 in the first unit column 18 and the second unit column 19 can also be more flexible. For example, referring to FIG. 5 again, in the first unit column 18, the buffer module 17, the logic module 16 and the latch module 15 in the shift unit 4 are arranged along the second direction y Accordingly, by arranging the first positive clock line CK1_1 and the first negative clock line CK1_2 at a side of the logic module 16 in the first unit column 18 away from the buffer module 17, a shorter connection distance between the clock signal line and the shift unit can be realized. In the second unit column 19, the latch module 15, the logic module 16 and the buffer module 17 in the shift unit 4 are arranged along the second direction y. Accordingly, by arranging the second positive clock line CK2_1 and the second negative clock line CK2_2 at a side of the logic module 16 in the second unit column 19 away from the buffer module 17, a shorter connection distance between the clock signal line and the shift unit can be realized. In some embodiment, as shown in FIG. 6, which is another structural schematic diagram of the control signal line 5 according to an embodiment of the present disclosure, the latch module 15, the logic module 16 and the buffer module 17 in the shift unit 4 in the first unit column 18 can also be arranged in the second direction y. At this time, by setting the first positive clock line CK1_1 and the first negative clock line CK1_2 at a side of the logic module 16 in the first unit column 18 away from the second unit column 19, it is also possible to achieve a shorter connection distance between the clock signal line and the shift unit 4.

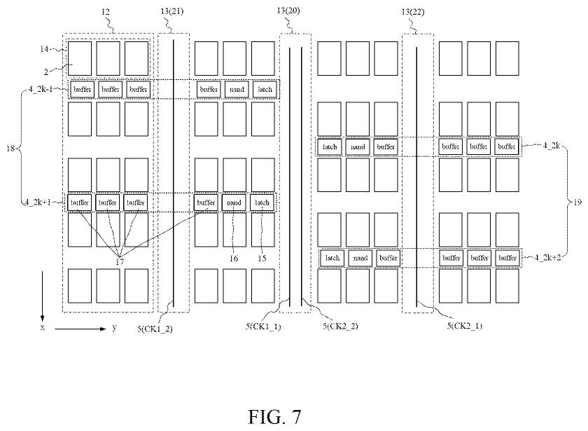

In some embodiments, as shown in FIG. 7 and FIG. 8, FIG. 7 is another structural schematic diagram of the control signal line 5 according to an embodiment of the present disclosure and FIG. 8 is a structural schematic diagram of layers according to an embodiment of the present disclosure. The display panel includes pixel columns 12 and spacing areas 13 alternately arranged along the second direction y. The pixel column 12 includes a plurality of pixels 14 arranged along the first direction x, and each of the plurality of pixels 14 includes at least two of the subpixels 2, and the first direction x intersects with the second direction y.

The spacing areas 13 include a first spacing area 20, and the first unit column 18 and the second unit column 19 are located at two sides of the first spacing area 20 in the second direction y, respectively. At least one of the first positive clock line CK1_1 and the first negative clock line CK1_2 is located in the first spacing area 20, and at least one of the second positive clock line CK2_1 and the second negative clock line CK2_2 is located in the first spacing area 20.

It should be noted that the first spacing area 20 described above refers to a spacing area 13 between some two pixel columns 12. As described above, a width of this kind of spacing area 13 is large.

In the above structure, the first unit column 18 and the second unit column 19 are arranged at two sides of the first spacing area 20, and at least one of the first positive clock line CK1_1 and the first negative clock line CK1_2 is located in the first spacing area 20, and at least one of the second positive clock line CK2_1 and the second negative clock line CK2_2 is located in the first spacing area 20, coupling between these clock signal lines located in the first spacing area 20 and the data line can be reduced, and line widths of these clock signal lines can be increased, so as to reduce the load and thus the voltage drop of the clock signal in transmission.

In some embodiments, referring to FIGS. 7 and 8 again, the display panel includes pixel columns 12 and spacing areas 13 alternately arranged along the second direction y. The pixel column 12 includes a plurality of pixels 14 arranged along the first direction x, and each of the plurality of pixels 14 includes at least two of the subpixels 2, and the first direction x intersects with the second direction y.

The spacing areas 13 include a second spacing area 21, the first unit column 18 is located at least at both sides of the second spacing area 21 in the second direction y, and at least one of the first positive clock line CK1_1 and the first negative clock line CK1_2 is located in the second spacing area 21. In some embodiments, the spacing areas 13 include a third spacing area 22, the second unit column 19 is located at least at both sides of the third spacing area 22 in the second direction y, and at least one of the second positive clock line CK2_1 and the second negative clock line CK2_2 is located in the third spacing area 22.

Taking the first unit column 18 as an example, in selecting an arranging position of the first unit column 18, the first unit column 18 is arranged at both sides of the second spacing area 21 in the second direction y, at least one of the first positive clock line CK1_1 and the first negative clock line CK1_2 can be arranged in the second spacing area 21, thereby providing a larger arranging space for it and further reducing the coupling.

In some embodiments, referring to FIG. 7 again, the shift unit 4 includes a latch module 15, a logic module 16 and a buffer module 17. The logic module 16 is electrically connected between the latch module 15 and the buffer module 17, and the buffer module 17 is electrically connected between the logic module 16 and the subpixel 2.

The first unit column 18 includes the odd-numbered stages of shift units 4, and the second unit column 19 includes the even-numbered stages of shift units 4. The latch module 15 in the first unit column 18 is electrically connected to the first positive clock line CK1_1, and the logic module 16 in the first unit column 18 is electrically connected to the first negative clock line CK1_2. The latch module 15 in the second unit column 19 is electrically connected to the second negative clock line CK2_2, and the logic module 16 in the second unit column 19 is electrically connected to the second positive clock line CK2_1. That is, it can be realized as described above that the latch module 15 in the odd-numbered stage of shift unit 4 receives a same clock signal as the logic module 16 in the even-numbered stage of shift unit 4, and the logic module 16 in the odd-numbered stage of shift unit 4 receives a same clock signal as the latch module 15 in the even-numbered stage of shift unit 4.

In some embodiments, in the shift unit 4 of the first unit column 18, the buffer module 17, the logic module 16 and the latch module 15 are arranged in a direction pointing from the first unit column 18 to the second unit column 19, while in the shift unit 4 of the second unit column 19, the buffer module 17, the logic module 16 and the latch module 15 are arranged in a direction pointing from the second unit column 19 to the first unit column 18. The first positive clock line CK1_1 and the second negative clock line CK2_2 are located between the first unit column 18 and the second unit column 19. The first negative clock line CK2_1 is located at a side of the latch module 15 in the first unit column 18 away from the second unit column 19, and the second positive clock line CK2_1 is located at a side of the latch module 15 in the second unit column 19 away from the first unit column 18.

Based on the above arrangement of respective modules in the shift unit 4 in the first and second unit columns 18 and 19, the latch module 15 in the first unit column 18 and the latch module 15 in the second unit column 19 are close to each other. Therefore, by arranging the first positive clock line CK1_1 and the second negative clock line CK2_2 between the first and second unit columns 18 and 19, a connection distance between the first positive clock line CK1_1 and the latch module 15 in the first unit column 18 is reduced, and a connection distance between the second negative clock line CK2_2 and the latch module 15 in the second unit column 19 is reduced. A connection distance between the first negative clock line CK1_2 and the logic module 16 in the first unit column 18 can be reduced by further arranging the first negative clock line CK1_2 at a side of the latch module 15 in the first unit column 18 away from the second unit column 19, for example, between the latch module 15 and the logic module 16. A connection distance between the second positive clock line CK2_1 and the logic module 16 in the second unit column 19 can be reduced by further arranging the second positive clock line CK2_1 at a side of the latch module 15 in the second unit column 19 away from the first unit column 18, for example, between the latch module 15 and the logic module 16.

Therefore, based on the arrangement described above, for each of the clock signal lines, a length of a connecting wiring between the clock signal line and the module connected to the clock signal line is short, which not only reduces signal delay on respective clock signal lines, but also improves uniformity of signal transmission on different clock signal lines.

In some embodiments, combined with FIGS. 7 and 8, the first unit column 18 and the second unit column 19 may be located at two sides of the first spacing area 20 in the second direction y, so that the first positive clock line CK1_1 and the second negative clock line CK2_2 are located in the first spacing area 20. Meanwhile, the first unit column 18 is located at a side of the second spacing area 21 in the second direction y, so that the first negative clock line CK2_1 is located in the second spacing area 21, and the second unit column 19 is located at a side of the third spacing area 22 in the second direction y, so that the second positive clock line CK2_1 is located in the third spacing area 22.

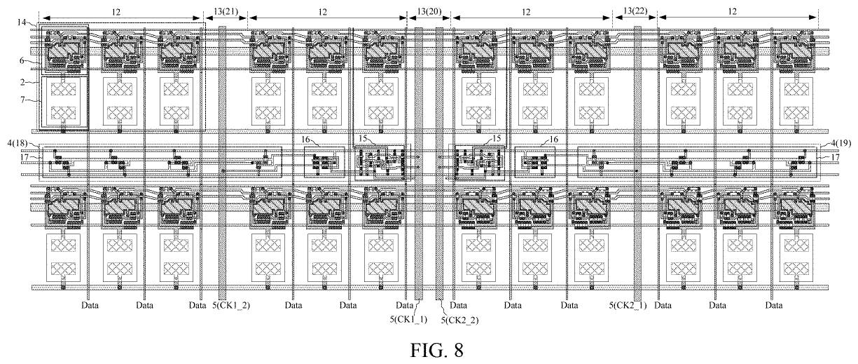

In a possible implementation, as shown in FIG. 9, which is a schematic diagram of another arranging position of a control signal line according to an embodiment of the present disclosure, the control signal line 5 includes a first positive clock line CK1_1 and a first negative clock line CK2_1.

In the shift register 3, a part of shift units 4 are arranged along the first direction x to form a first unit column 18, and a remaining part of shift units 4 are arranged along the first direction x to form a second unit column 19. The first unit column 18 and the second unit column 19 are arranged along the second direction y, and the first direction x intersects with the second direction y. The shift units 4 in the first unit column 18 are electrically connected to the first positive clock line CK1_1 and the first negative clock line CK1_2 respectively, and the shift units 4 in the second unit column 19 are electrically connected to the first positive clock line CK1_1 and the first negative clock line CK1_2 respectively. The first positive clock line CK1_1 and the first negative clock line CK1_2 are located between the first unit column 18 and the second unit column 19.

By electrically connecting the first unit column 18 and the second unit column 19 with only one set of clock signal lines, a number of clock signal lines to be set can be reduced, and coupling between the clock signal lines and other signal lines in the display area 1 can be reduced. In addition, by arranging the first positive clock line CK1_1 and the first negative clock line CK1_2 between the first unit column 18 and the second unit column 19, lengths of connecting wirings between the first unit column 18 and the second unit column 19 and these two clock signal lines tend to be the same, and thus uniformity of the clock signals received by the shift units 4 in the first unit column 18 and the second unit column 19 can be improved.

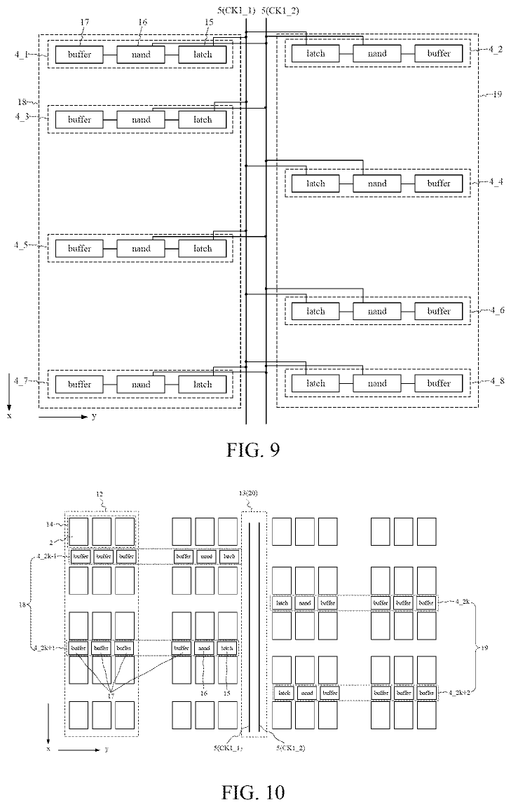

In some embodiments, as shown in FIG. 10, which is a schematic diagram of an arranging position of the control signal line 5 according to an embodiment of the present disclosure, the display panel includes pixel columns 12 and spacing areas 13 alternately arranged along the second direction y. The pixel column 12 includes a plurality of pixels 14 arranged along the first direction x, and each of the plurality of pixels 14 includes at least two of the subpixels 2, and the first direction x intersects with the second direction y. The spacing areas 13 include a first spacing area 20, and the first unit column 18 and the second unit column 19 are respectively located at two sides of the first spacing area 20 in the second direction y. The first positive clock line CK1_1 and the first negative clock line CK1_2 are located in the first spacing area 20.

As described above, the spacing area 13 between two adjacent pixel columns 12 has a large width. Therefore, by arranging the first unit column 18 and the second unit column 19 at two sides of the first spacing area 20 and arranging the first positive clock line CK1_1 and the first negative clock line CK1_2 in the first spacing area 20, there is a large arranging space for the first positive clock line CK1_1 and the first negative clock line CK1_2, which can not only reduce coupling between this part of the clock signal lines and the data line, but also increase line widths of this part of the clock signal lines to a certain extent, and reduce the voltage drop of the clock signal in transmission.

In some embodiments, combined with FIGS. 9 and 10, the shift unit 4 includes the latch module 15, the logic module 16 and the buffer module 17. The logic module 16 is electrically connected between the latch module 15 and the buffer module 17, and the buffer module 17 is electrically connected between the logic module 16 and the subpixel 2. In the odd-numbered stage of shift unit 4, the latch module 15 is electrically connected to the first positive clock line CK1_1 and the logic module 16 is electrically connected to the first negative clock line CK1_2. In the even-numbered stage of shift unit 4, the latch module 15 is electrically connected to the first negative clock line CK1_2 and the logic module 16 is electrically connected to the first positive clock line CK1_1.

In the shift unit 4 of the first unit column 18, the buffer module 17, the logic module 16 and the latch module 15 are arranged in a direction pointing from the first unit column 18 to the second unit column 19, while in the shift unit 4 of the second unit column 19, the buffer module 17, the logic module 16 and the latch module 15 are arranged in a direction pointing from the second unit column 19 to the first unit column 18.

At this time, the logic module 16 and the latch module 15 in the first unit column 18 are close to the first positive clock line CK1_1 and the first negative clock line CK1_2, and the logic module 16 and the latch module 15 in the second unit column 19 are also close to the first positive clock line CK1_1 and the first negative clock line CK1_2, so that the first positive clock line CK1_1 and the first negative clock line CK1_2 have smaller and similar connection distances with the first unit column 18 and the second unit column 19 respectively, thereby reducing delay and attenuation of clock signals and improving uniformity of clock signals received by shift units 4 in the first unit column 18 and the second unit column 19.

In a possible implementation, combined with FIGS. 5 and 9, when the shift register 3 is divided into the first unit column 18 and the second unit column 19, the first unit column 18 includes the odd-numbered stages of shift units 4 and the second unit column 19 includes the even-numbered stages of shift units 4.

Combined with the above-described connection relationship between the odd-numbered stages of shift units 4 and the even-numbered stages of shift units 4 with the clock signal lines, the following can be realized in the embodiment of the present disclosure by arranging the first unit column 18 to include all of the odd-numbered stages of shift units 4 and the second unit column 19 to include all of the even-numbered stages of shift units 4: the latch module 15 and the logic module 16 of each shift unit 4 in the first unit column 18 can be connected to two clock signal lines in a corresponding set of clock signal lines in a same way;

the latch module 15 and the logic module 16 of each shift unit 4 in the second unit column 19 are connected to two clock signal lines in a corresponding set of clock signal lines in a same way, so the design difficulty of connecting wirings between the two unit columns and the clock signal lines is smaller, and arrangement of the connecting wirings is more regular.

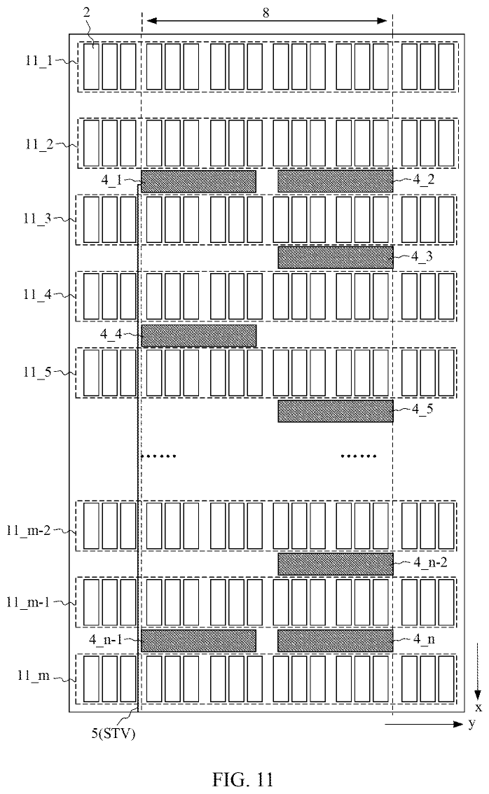

In some embodiments, as shown in FIG. 11, which is a schematic diagram of another arranging position of a control signal line according to an embodiment of the present disclosure, the shift register 3 includes a first stage of shift unit 4_1 to an n-th stage of shift unit 4_n, and the first stage of shift unit 4_1 to the n-th stage of shift unit 4_n sequentially output driving signals, with n>1. In some embodiments, the control signal lines 5 further include a frame start signal line STY, which is electrically connected to the first stage of shift unit 4_1 and located in the display area 1.

In the above arrangement, by arranging the frame start signal line STY in the display area 1, a length of a connecting wiring between the frame start signal line STV and the first stage of shift unit 4_1 can be reduced, and delay and attenuation of the frame start signal can be reduced, so that the shift register 3 can respond to the frame start signal in time.

In some embodiments, referring to FIG. 11 again, the display area 1 includes a register arranging area 8, the shift register 3 is located in the register arranging area 8, and the frame start signal line STV is located at a side of the register arranging area 8.

Compared with the clock signal line which may be electrically connected to each of the shift units 4, the frame start signal line STY is only electrically connected to the first stage of shift unit 4_1, so only a wiring length between the frame start signal line STY and the first stage of shift unit 4_1 may be considered. The frame start signal line STV is located at a side of the register arranging area 8, that is, at a side of the first stage of shift unit 4_1, so that a distance between the frame start signal line STV and the first stage of shift unit 4_1 can be greatly reduced. In addition, the frame start signal line STV is arranged outside the register arranging area 8, and the number of control signal lines 5 arranged in the register arranging area 8 can be avoided to be excessive, and excessive coupling between the control signal lines 5 and data lines in the register arranging area 8 also can be avoided.

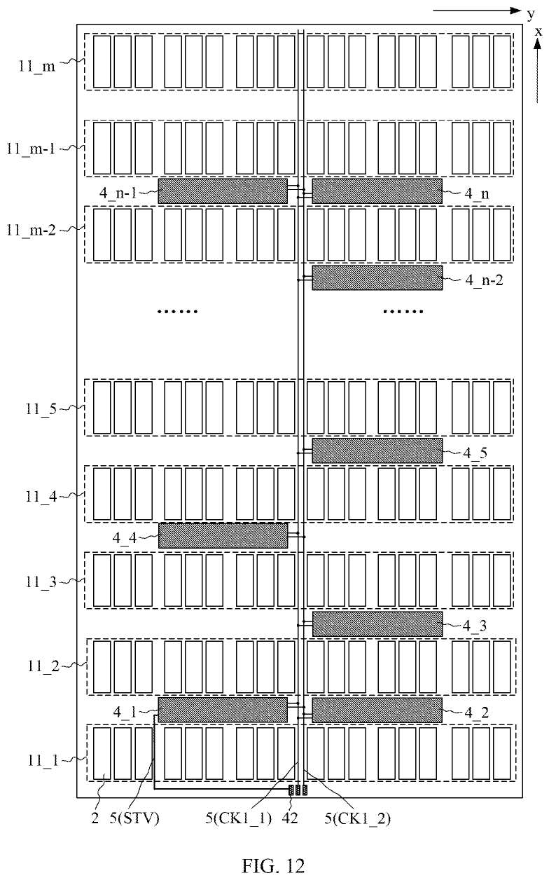

In some embodiments, as shown in FIG. 12, which is a schematic diagram of another arranging position of a control signal line 5 according to an embodiment of the present disclosure, the display panel further includes connecting pins 42, which are configured to provide signals to the control signal lines 5. For example, combined with FIG. 9, when the shift units 4 are electrically connected to the first positive clock line CK1_1 and the first negative clock line CK1_2 respectively, the connection pins 42 are configured to provide signals to the frame start signal line STV, the first positive clock line CK1_1 and the first negative clock line CK1_2, and the first stage of shift unit 4_1 is located at a side close to the connection pins 42.

In this arrangement, the first stage of shift unit 4_1 is located close to a lower edge of the display panel, and the shift register 3 scans from bottom to top, that is, from the first stage to the last stage. At this time, the frame start signal line STV can be electrically connected to the first stage of shift unit 4_1 without passing through the display area 1. On the one hand, the frame start signal line STV has a smaller length, and the delay and attenuation of the frame start signal are very small; on the other hand, the frame start signal line STV can be prevented from passing through the display area, thereby avoiding large coupling with the data line.

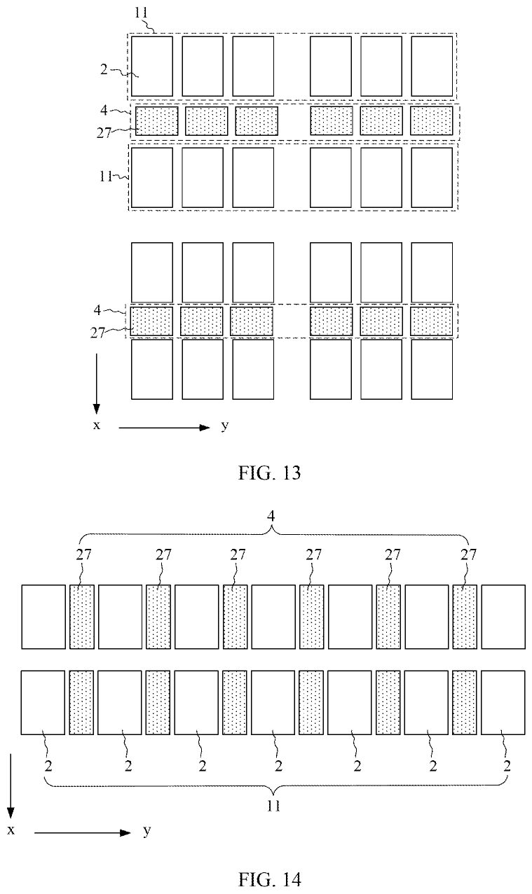

In some embodiments, as shown in FIGS. 13 and 14, FIG. 13 is a schematic arranging diagram of subunits 27 in the shift unit 4 according to the embodiment of the present disclosure, and FIG. 14 is another schematic arranging diagram of subunits 27 in the shift unit 4 according to the embodiment of the present disclosure. The display panel includes a plurality of pixel rows 11 arranged along a first direction x, and each of the plurality of pixel rows 11 includes at least two of the subpixels 2 arranged along the second direction y, and the first direction x intersects with the second direction y.

The shift unit 4 is divided into a plurality of subunits 27, and one subunit 27 is located at a side of one subpixel 2. Referring to FIG. 13, the subunit 27 in the shift unit 4 is located at a side of a subpixel 2 in a same pixel row 11 in the first direction x; or referring to FIG. 14, the subunit 27 in the shift unit 4 is located at a side of the subpixel 2 in the same pixel row 11 in the second direction y.

Due to a large number of devices in a single shift unit 4, the shift unit 4 is divided into a plurality of subunits 27, which are distributed at a side of the subpixel 2 in the same pixel row 11 in the second direction y or at a side of the subpixel 2 in the same pixel row 11 in the first direction x. The plurality of subunits 27 included in one shift unit 4 can be arranged along the second direction y, which is more conducive to electrical connection between the shift unit 4 and the pixel row 11.

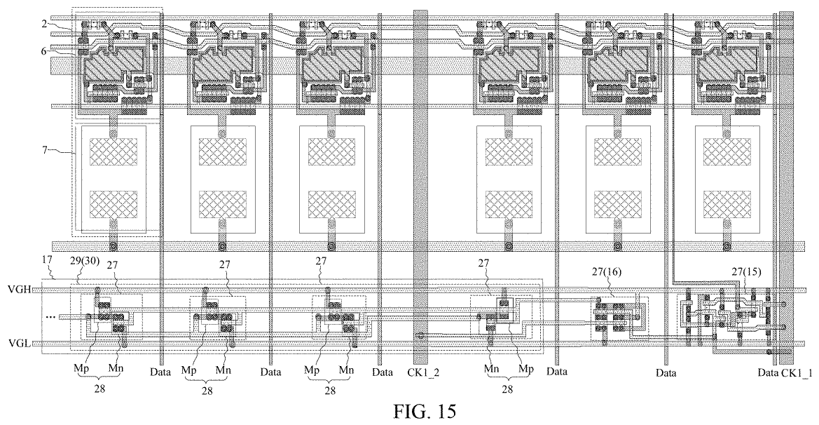

In a possible implementation, as shown in FIG. 15, which is a schematic view of another film structure of a display panel according to an embodiment of the present disclosure, the shift unit 4 is divided into a plurality of subunits 27, and one subunit 27 is located at a side of one subpixel 2.

Referring to FIG. 4, the shift unit 4 includes a buffer module 17, which includes x complementary metal oxide semiconductor devices 28, and each of the x complementary metal oxide semiconductor devices 28 includes a P-type transistor Mₚ and an N-type transistor Mₙ. Gates of the P-type transistor Mₚ and the N-type transistor Mₚ are electrically connected to each other, second electrodes of the P-type transistor Mₚ and the N-type transistor Mₙ are electrically connected to each other, a first electrode of the P-type transistor Mₚ is electrically connected to a first fixed potential signal line VGH, and a first electrode of the N-type transistor Mₙ is electrically connected to a second fixed potential signal line VGL.

The P-type transistor Mₚ and the N-type transistor Mₙ in a complementary metal oxide semiconductor device 28 are configured to realize a same logic function.

The x complementary metal oxide semiconductor devices 28 are divided into 37 subunits 27, and the P-type transistor Mₚ and N-type transistor Mₙ in a same complementary metal oxide semiconductor device 28 belong to a same subunit 27, where x>1 and 1<y<x.

For the complementary metal oxide semiconductor device 28, if a distance between the P-type transistor Mₚ and the N-type transistor Mₙ is too large, interference by other signals may occur, thus resulting in a function failure of the complementary metal oxide semiconductor device 28, and then a circuit function failure. Therefore, in the embodiment of the present disclosure, by arranging the P-type transistor Mₚ and the N-type transistor Mₙ in a same complementary metal oxide semiconductor device 28 into a same subunit 27, the distance between the P-type transistor Mₚ and the N-type transistor Mₙ in the same complementary metal oxide semiconductor device 28 can be made small so as to improve reliability of the complementary metal oxide semiconductor device 28. In addition, gates of the two transistors in the same complementary metal oxide semiconductor device 28 are electrically connected to each other, and the second electrodes of them are also electrically connected to each other. Therefore, when the two transistors in the same complementary metal oxide semiconductor device 28 are arranged into the same subunit 27, layout design can also be optimized.

In some embodiments, combined with FIGS. 4 and 15, the buffer module 17 includes a plurality of buffer submodules 29 which are cascaded in sequence, and each buffer submodule 29 includes at least one complementary metal oxide semiconductor device 28. In order to improve voltage stability of the buffer module 17, the buffer submodule 29 includes a first buffer submodule 30, and the first buffer submodule 30 includes at least two complementary metal oxide semiconductor devices 28 arranged in parallel.

In an arrangement, each of buffer submodules 29 in the buffer module 17 may include at least two complementary metal oxide semiconductor devices 28 arranged in parallel. In some embodiments, in another arrangement, only part of the buffer submodules 29 in the buffer module 17 includes at least two complementary metal oxide semiconductor devices 28 arranged in parallel. For example, the first stage of buffer submodule 29 includes one complementary metal oxide semiconductor device 28, and the second stage of buffer submodule 29 through the k-th stage of buffer submodule 29 each include at least two complementary metal oxide semiconductor devices 28 arranged in parallel. In this structure, the second stage of buffer submodule 29 through the k-th stage of buffer submodule 29 are all the first buffer submodules 30. In some embodiments, the first stage of buffer submodule 29 through the k-1-th stage of buffer submodule 29 each include only one complementary metal oxide semiconductor device 28, and the k-th stage of buffer submodule 29 includes at least two complementary metal oxide semiconductor devices 28 arranged in parallel. In this structure, only the k-th stage of buffer submodule 29 is the first buffer submodule 30.

In some embodiments, referring to FIG. 15 again, x=y. That is, in subunits 27 of the buffer module 17, one subunit 27 only includes one complementary metal oxide semiconductor device 28, thus avoiding mutual interference between devices caused by an excessively number of devices in one subunit 27.

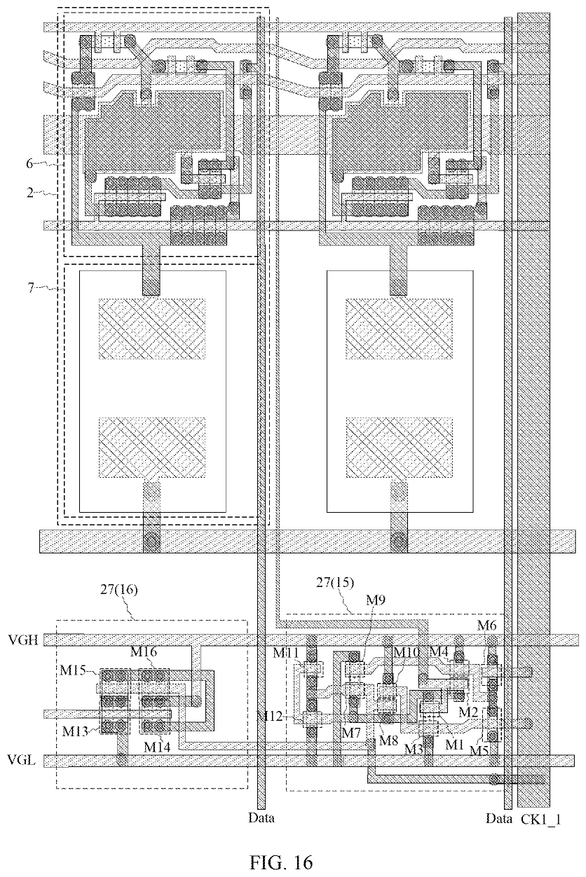

In some embodiments, combined with FIGS. 4 and 15, and as shown in FIG. 16 which is a schematic view of still another film structure of a display panel according to an embodiment of the present disclosure, the shift unit 4 is divided into a plurality of subunits 27, and one subunit 27 is located at a side of one subpixel 2. The shift unit 4 includes a latch module 15, and the latch module 15 is divided into two subunits 27 at most.

Combined with the circuit structure of the latch module 15 shown in FIG. 4, generally, the latch module 15 only includes transistors and but no voltage stabilizing capacitor. If the latch module 15 is divided into an excessively number of subunits 27 and when these subunits 27 are located at sides of multiple subpixels 2, there are more overlaps between connection wirings of these subunits 27 and the data line Data. Since the latch module 15 in the first-stage of shift unit 4 is only refreshed once in a frame period, the output signal of the latch module 15 is maintained by self-locking of a first fixed voltage provided by the first fixed potential signal line VGH and a second fixed voltage provided by the second fixed potential signal line VGL in an unrefreshing time in the frame period. If the latch module 15 is divided into the excessively number of subunits 27, connection wirings between these subunits 27, that is, there are more overlaps between the connection wirings inside the latch module 15 and the data line DATA, which causes the latch module 15 to be greatly interfered, making it difficult for the latch module 15 to maintain the output voltage, and resulting in a function failure of the latch module 15. Therefore, according to the embodiment of the present disclosure, the latch module 15 is divided into two subunits 27 at most, which can reduce overlapping between the connection wirings inside the latch module 15 and the data line Data, and further improve stability of an operation state of the latch module 15.

In some embodiments, referring to FIG. 16 again, one latch module 15 is arranged to include one subunit 27. At this time, the connection wirings inside the latch module 15 do not overlap with the data line Data, which further reduces interference of data signals to the latch module 15.

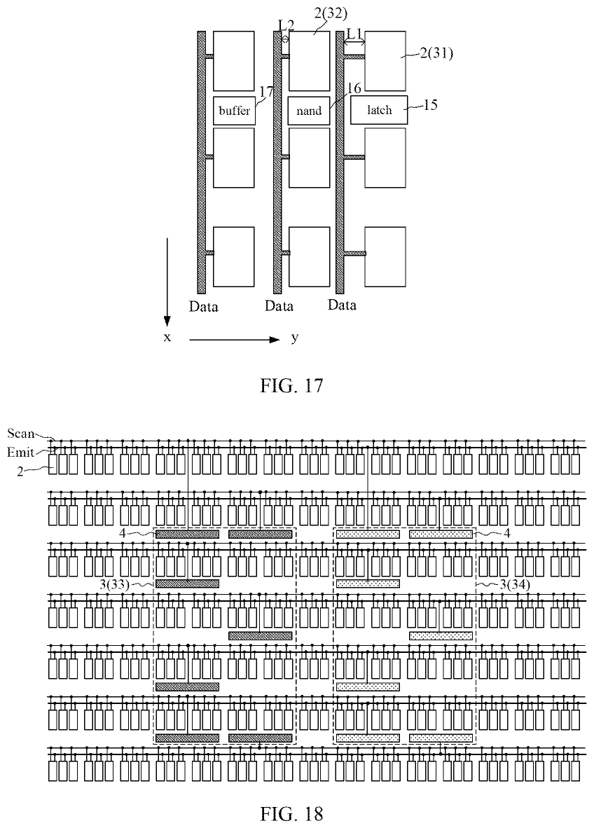

In some embodiments, as shown in FIG. 17, which is a structural diagram of a data line according to an embodiment of the present disclosure, the subpixels 2 include a first subpixel 31 and a second subpixel 32, and the latch module 15 is located at a side of the first subpixel 31 in the first direction x. In some embodiments, the display panel includes data lines Data each extending in the first direction x, and a distance L1 between the first subpixel 31 and a respective data line Data electrically connected to the first subpixel is larger than a distance L2 between the second subpixel 32 and a respective data line electrically connected to the second subpixel.

The latch module 15 includes a large number of transistors, and thus occupies a large space. Therefore, when the latch module 15 is located at a side of the first subpixel 31 in the first direction x, by increasing a distance with the data line Data electrically connected to the first subpixel 31, not only a larger arranging space can be reserved for the latch module 15, but also the distance between the data line Data and the latch module 15 can be increased, and interference of the data signals on the data line Data to the latch module 15 can be reduced to a greater extent.

In some embodiments, referring to FIGS. 5 and 9, the shift unit 4 includes the latch module 15, the logic module 16 and the buffer module 17. The logic module 16 is electrically connected between the latch module 15 and the buffer module 17, and the buffer module 17 is electrically connected between the logic module 16 and the subpixel 2.

In the shift register 3, a part of shift units 4 are arranged along the first direction x to form a first unit column 18, and another part of shift units 4 are arranged along the first direction x to form a second unit column 19. The first unit column 18 and the second unit column 19 are arranged along the second direction y, and the first direction x intersects with the second direction y. In the shift unit 4 of the first unit column 18, the buffer module 17, the logic module 16 and the latch module 15 are arranged in a direction pointing from the first unit column 18 to the second unit column 19, while in the shift unit 4 of the second unit column 19, the buffer module 17, the logic module 16 and the latch module 15 are arranged in a direction pointing from the second unit column 19 to the first unit column 18.

Combined with above description of specific structures of the shift unit 4, in two adjacent stages of shift units 4, the latch module 15 in the previous stage of shift unit 4 may be electrically connected to the latch module 15 in the later stage of shift unit 4 so as to realize the shift function. With the above arrangement, the latch modules 15 in the first unit column 18 and the second unit column 19 are relatively close to each other. Therefore, when the latch modules 15 in the adjacent two stage shift units 4 are electrically connected to each other, a connection distance between the two latch modules 15 is relatively small, so that overlapping between this part of connecting wirings and other signal lines can be reduced, and the coupling can be reduced, thus improving reliability of shift.

It should be noted that with a different specific circuit structure of the shift unit 4, a number of subunits 27 included in the shift unit 4 is also different. In one design, one shift unit 4 can be divided into 18 subunits 27, and these 18 subunits 27 can be located on sides of the 18 subpixels 2 in the first direction x, that is, they may consume space next to 6 pixels 4.

In some embodiments, as shown in FIG. 15, the display panel includes the data lines Data, which are located in the display area 1 and electrically connected to the subpixels 2, and the control signal line 5 is arranged in a same layer as the data line Data. At this time, the control signal lines 5 and the data lines Data are formed by a same patterning process, so as to simplify a processing flow and reduce process cost.

In a possible embodiment, as shown in FIG. 15, the subpixel 2 includes a pixel circuit 6 and a light-emitting diode 7, and the pixel circuit 6 is electrically connected to the shift unit 4 and the light-emitting diode 7, respectively. The light-emitting diode 7 has advantages of a low driving voltage and high luminous efficiency, which can significantly improve display performance of the display panel. In the embodiment of the present disclosure, the light-emitting diode 7 can be a mini LED or a micro LED.

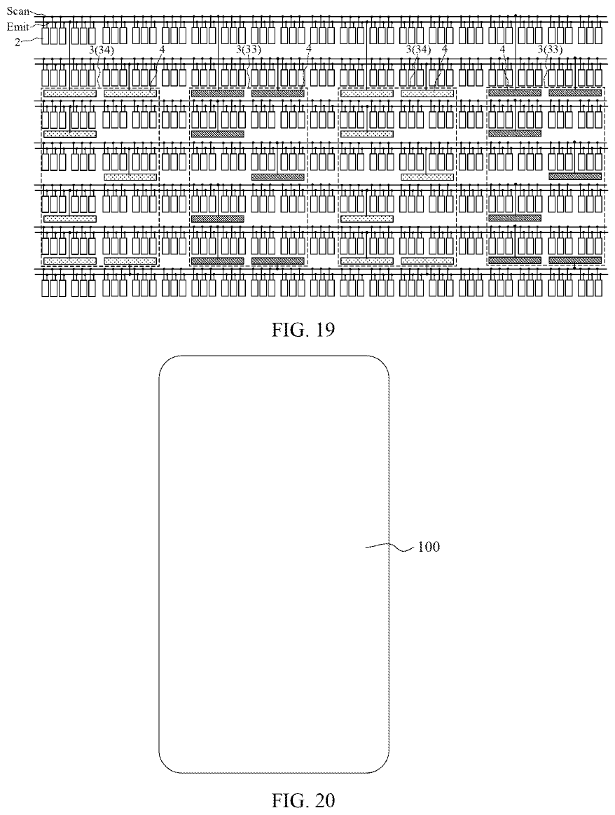

In a possible implementation, as shown in FIG. 18 and FIG. 19, FIG. 18 is a structural diagram of a shift register 3 according to an embodiment of the present disclosure and FIG. 19 is another structural diagram of a shift register 3 according to an embodiment of the present disclosure. The shift register 3 includes at least one scanning shift register 33 and/or at least one emission shift register 34. The scanning shift register 33 is electrically connected to the subpixel 2 through a scanning signal line Scan, and the emission shift register 34 is electrically connected to the subpixel 2 through a light emission signal line Emit.

It should be noted that, referring to FIG. 18, the display panel may only include one scanning shift register 33 and one emission shift register 34. The one scanning shift register 33 provides a driving signal to one end of the scanning signal line Scan, and the one emission shift register 34 provides a driving signal to one end of the light-emitting signal line Emit. In some embodiments, referring to FIG. 19, the display panel may include two scanning shift registers 33 and two emission shift registers 34. The two scanning shift registers 33 provide the driving signal to two ends of the scan signal line Scan, and the emission shift registers 34 provide the driving signal to two ends of the light-emitting signal line Emit, thereby improving a refresh rate and reducing attenuation of the scan signal and the light-emitting signal in transmission.

Based on a same inventive concept, a display apparatus is provided in an embodiment of the present disclosure, as shown in FIG. 20, which is a schematic structural diagram of a display apparatus according to an embodiment of the present disclosure, and the display apparatus includes the display panel 100 described above. A specific structure of the display panel 100 has been described in detail in the above-mentioned embodiments, which will not be repeatedly described here again. Of course, the display apparatus shown in FIG. 20 is only a schematic illustration, and the display apparatus can be any electronic device with a display ftinction, such as a mobile phone, a tablet computer, a notebook computer, a wearable electronic product or a vehicle-mounted electronic product or the like.

The above are only preferred embodiments of the present disclosure, but not intended to limit the present disclosure. Any modifications, equivalents, improvements, etc. made within the spirit and principle of the present disclosure should be encompassed within the scope of the present disclosure.

Finally, it should be noted that the above embodiments are only intended to illustrate technical schemes of the present disclosure, but not to limit it. Although the present disclosure has been described in detail with reference to the foregoing embodiments, it should be understood by ordinary skilled in the art that modifications can be made to the technical schemes described in the foregoing embodiments, or equivalent substitutions can be made to part or all of technical features thereof These modifications or substitutions do not cause essence of corresponding technical schemes to depart from the spirit and scope of the technical schemes of the embodiments of this disclosure.

1. A display panel having a display area, comprising:
subpixels located in the display area; and
a shift register comprising a plurality of stages of shift units that is cascaded, each of the plurality of stages of shift units being electrically connected to one of control signal lines and at least one of the subpixels, and configured to output a driving signal to the at least one of the subpixels in response to a control signal,
wherein the shift register is located in the display area, and at least one control signal line of the control signal lines is located in the display area.

2. The display panel according to claim 1, wherein the display area comprises a register arranging area, the shift register is located in the register arranging area, and the at least one control signal line is located in the register arranging area.

3. The display panel according to claim 1, wherein the subpixels define a plurality of pixel rows of the display panel arranged along a first direction, wherein each of the plurality of pixel rows comprises at least two of the subpixels arranged along a second direction intersecting with the first direction; wherein each of the plurality of stages of shift units is located between two adjacent pixel rows of the plurality of pixel rows, and both a first stage of shift unit and a second stage of shift unit of the plurality of stages of shift units are located between a second pixel row and a third pixel row of the plurality of pixel rows; and
the display panel further comprises a first panel edge extending in the second direction, a first pixel row of the plurality of pixel rows is adjacent to the first panel edge, the second pixel row is located at a side of the first pixel row away from the first panel edge, and the third pixel row is located at a side of the second pixel row away from the first panel edge.

4. The display panel according to claim 1, wherein the subpixels define pixels, the pixels define a plurality of pixel columns of the display panel, and the plurality of pixel columns and a plurality of spacing areas are alternately arranged along a second direction,
wherein each of the plurality of pixel columns comprises at least two of the pixels arranged along a first direction, and the first direction intersects with the second direction; and
the at least one control signal line is located in one of the plurality of spacing areas.

5. The display panel according to claim 1, wherein at least two of the plurality of stages of shift units in the shift register are arranged in a first direction to form a first unit column, at least another two of the plurality of stages of shift units are arranged in the first direction to form a second unit column, the first unit column and the second unit column are arranged in a second direction, and the first direction intersects with the second direction;
the control signal lines comprise a first positive clock line, a first negative clock line, a second positive clock line, and a second negative clock line, wherein, at a same moment, a signal provided by the first positive clock line and a signal provided by the second positive clock line are the same, and a signal provided by the first negative clock line and a signal provided by the second negative clock line are the same; and
the at least two of the plurality of stages of shift units in the first unit column are electrically connected to the first positive clock line and the first negative clock line, and the at least another two of the plurality of stages of shift units in the second unit column are electrically connected to the second positive clock line and the second negative clock line.

6. The display panel according to claim 5, wherein the subpixels define pixels, the pixels define a plurality of pixel columns of the display panel, and the plurality of pixel columns and a plurality of spacing areas are alternately arranged along a second direction,
wherein each of the plurality of pixel columns comprises at least two of the pixels arranged along a first direction, and the first direction intersects with the second direction;
the plurality of spacing areas comprises a first spacing area, and the first unit column and the second unit column are respectively located at two sides of the first spacing area in the second direction; and
at least one of the first positive clock line or the first negative clock line is located in the first spacing area, and at least one of the second positive clock line or the second negative clock line is located in the first spacing area.

7. The display panel according to claim 5, wherein the subpixels define pixels, the pixels define a plurality of pixel columns of the display panel, and the plurality of pixel columns and a plurality of spacing areas are alternately arranged along a second direction, wherein each of the plurality of pixel columns comprises at least two of the pixels arranged along a first direction, and the first direction intersects with the second direction; and
the plurality of spacing areas comprises a second spacing area, the first unit column is located at least at both sides of the second spacing area in the second direction, and at least one of the first positive clock line or the first negative clock line is located in the second spacing area;
the plurality of spacing areas comprise a third spacing area, the second unit column is located at least at both sides of the third spacing area in the second direction, and at least one of the second positive clock line or the second negative clock line is located in the third spacing area; or
the plurality of spacing areas comprise both a second spacing area the first unit column is located at least at both sides of the second spacing area in the second direction, and at least one of the first positive clock line or the first negative clock line is located in the second spacing area and a third spacing area, the second unit column is located at least at both sides of the third spacing area in the second direction, and at least one of the second positive clock line or the second negative clock line is located in the third spacing area.

8. The display panel according to claim 5, wherein each of the plurality of stages of shift units comprises a latch module, a logic module, and a buffer module, wherein the logic module is electrically connected between the latch module and the buffer module, and the buffer module is electrically connected between the logic module and one of the plurality of subpixels;
the first unit column comprises odd-numbered stages of shift units of the plurality of stages of shift units, the second unit column comprises even-numbered stages of shift units of the plurality of stages of shift units, the latch modules of the at least two of the plurality of stages of shift units in the first unit column are electrically connected to the first positive clock line, the logic modules of the at least two of the plurality of stages of shift units in the first unit column are electrically connected to the first negative clock line, the latch modules of the at least another two of the plurality of stages of shift units in the second unit column are electrically connected to the second negative clock line, and the logic modules of the at least another two of the plurality of stages of shift units in the second unit column are electrically connected to the second positive clock line;
in one of the at least two of the plurality of stages of shift units in the first unit column, the buffer module, the logic module, and the latch module are arranged in a direction from the first unit column to the second unit column, while in one of the at least another two of the plurality of stages of shift units in the second unit column, the buffer module, the logic module, and the latch module are arranged in a direction from the second unit column to the first unit column; and
the first positive clock line and the second negative clock line are located between the first unit column and the second unit column, the first negative clock line is located at a side of the latch module in the first unit column away from the second unit column, and the second positive clock line is located at a side of the latch module in the second unit column away from the first unit column.

9. The display panel according to claim 1, wherein the control signal lines comprise a first positive clock line and a first negative clock line;
at least two of the plurality of stages of shift units in the shift register are arranged in a first direction to form a first unit column, at least another two of the plurality of stages of shift units are arranged in the first direction to form a second unit column, the first unit column and the second unit column are arranged in a second direction, and the first direction intersects with the second direction; and
the at least two of the plurality of stages of shift units in the first unit column are electrically connected to the first positive clock line and the first negative clock line, and the at least another two of the plurality of stages of shift units in the second unit column are electrically connected to the first positive clock line and the first negative clock line, and the first positive clock line and the first negative clock line are located between the first unit column and the second unit column.

10. The display panel according to claim 9, wherein the subpixels define pixels, the pixels define a plurality of pixel columns of the display panel, and the plurality of pixel colunms and a plurality of spacing areas are alternately arranged along a second direction, wherein each of the plurality of pixel columns comprises at least two of the pixels arranged along a first direction, and the first direction intersects with the second direction;
the plurality of spacing areas comprises a first spacing area, and the first unit column and the second unit column are respectively located at two sides of the first spacing area in the second direction; and
the first positive clock line and the first negative clock line are located in the first spacing area.

11. The display panel according to claim 9, wherein each of the plurality of stages of shift units comprises a latch module, a logic module, and a buffer module, wherein the logic module is electrically connected between the latch module and the buffer module, and the buffer module is electrically connected between the logic module and one of the subpixels;
the latch module is electrically connected to the first positive clock line in an odd-numbered stage of the plurality of stages of shift units, and the logic module is electrically connected to the first negative clock line; in an even-numbered stage of the plurality of stages of shift units, the latch module is electrically connected to the first negative clock line and the logic module is electrically connected to the first positive clock line; and
in one of the at least two of the plurality of stages of shift units in the first unit column, the buffer module, the logic module, and the latch module are arranged in a direction from the first unit column to the second unit column; and, in one of the at least another two of the plurality of stages of shift units in the second unit column, the buffer module, the logic module, and the latch module are arranged in a direction from the second unit column to the first unit column.

12. The display panel according to claim 5, wherein the first unit column comprises odd-numbered stages of the plurality of stages of shift units, and the second unit column comprises even-numbered stages of the plurality of stages of shift units.

13. The display panel according to claim 1, wherein the plurality of stages of shift units of the shift register comprises a first stage of shift unit through an n-th stage of shift unit, and the first stage of shift unit through the n-th stage of shift unit sequentially output driving signals, where n>1; and
the control signal lines further comprise a frame start signal line, wherein the frame start signal line is electrically connected to the first stage of shift unit and located in the display area.

14. The display panel according to claim 13, wherein the display area comprises a register arranging area, the shift register is located in the register arranging area, and the frame start signal line is located at a side of the register arranging area.

15. The display panel according to claim 13, further comprising a connecting pin, wherein the first stage of shift unit of the plurality of stages of shift units is located at a side close to the connecting pin.

16. The display panel according to claim 1, wherein the subpixels define a plurality of pixel rows of the display panel arranged along a first direction, wherein each of the plurality of pixel rows comprises at least two of the subpixels arranged along a second direction intersecting with the first direction; and
one of the plurality of stages of shift units comprises a plurality of subunits, wherein one of the plurality of subunits is located at a side of one of the subpixels; and the plurality of subunits in the one of the plurality of stages of shift units is located at sides of at least two of the subpixels in one of the plurality of pixel rows in the second direction, or the plurality of subunits in the one of the plurality of stages of shift units is located at sides of at least two of the subpixels in one of the plurality of pixel rows in the first direction, respectively.

17. The display panel according to claim 1, wherein one of the plurality of stages of shift units comprises a plurality of subunits, wherein one of the plurality of subunits is located at a side of one of the subpixels;
each of the plurality of stages of shift units comprises a buffer module, wherein the buffer module comprises x complementary metal oxide semiconductor devices, and each of the x complementary metal oxide semiconductor devices comprises a P-type transistor and an N-type transistor; and
the x complementary metal oxide semiconductor devices are allocated to y subunits, and the P-type transistor and the N-type transistor in one of the x complementary metal oxide semiconductor devices belong to a same one of the plurality of subunits, where x>1 and 1<y<x.

18. The display panel according to claim 17, wherein the buffer module comprises a plurality of buffer submodules that are cascaded in sequence, wherein each of the plurality of buffer submodules comprises at least one of the x complementary metal oxide semiconductor devices; and
the plurality of buffer submodules comprises a first buffer submodule, wherein the first buffer submodule comprises at least two complementary metal oxide semiconductor devices of the x complementary metal oxide semiconductor devices connected in parallel.

19. The display panel according to claim 17, wherein x=y.

20. The display panel according to claim 1, wherein one of the plurality of shift units comprises a plurality of subunits, wherein one of the plurality of subunits is located at a side of one of the subpixels; and
the one of plurality of shift units further comprises a latch module, wherein the latch module is allocated into two of the plurality of subunits at most.

21. The display panel according to claim 20, wherein the latch module is allocated into one of the plurality of subunits.

22. The display panel according to claim 20, wherein the subpixels comprise a first subpixel and a second subpixel, and the latch module is located at a side of the first subpixel in a first direction; and
the display panel further comprises data lines each extending in the first direction, and a distance between the first subpixel and one of the data lines that is electrically connected to the first subpixel is greater than a distance between the second subpixel and another one of the data lines that is electrically connected to the second subpixel.

23. The display panel according to claim 1, wherein each of the plurality of stages of shift units comprises a latch module, a logic module, and a buffer module, wherein the logic module is electrically connected between the latch module and the buffer module, and the buffer module is electrically connected between the logic module and one of the subpixels;
at least two of the plurality of stages of shift units are arranged in the shift register in a first direction to form a first unit column, at least another two of the plurality of stages of shift units are arranged in the first direction to form a second unit column, the first unit column and the second unit column are arranged in a second direction, and the first direction intersects with the second direction; and
in one of the at least two of the plurality of stages of shift units in the first unit column, the buffer module, the logic module, and the latch module are arranged in a direction from the first unit column to the second unit column, while in one of the at least another two of the plurality of stages of shift units in the second unit column, the buffer module, the logic module, and the latch module are arranged in a direction from the second unit column to the first unit column.

24. The display panel according to claim 1, further comprising data lines located in the display area and electrically connected to the subpixels, wherein the control signal lines and the data lines are arranged in a same layer.

25. The display panel according to claim 1, wherein at least one of the subpixels each comprises a pixel circuit and a light-emitting diode, wherein the pixel circuit is electrically connected to the light-emitting diode and one of the plurality of stages of shift units.

26. The display panel according to claim 1, wherein the shift register comprises:
at least one scanning shift register electrically connected to at least one of the subpixels through a scanning signal line; and/or at least one emission shift register electrically connected to at least one of the subpixels through a light-emitting signal line.

27. A display apparatus, comprising a display panel having a display area, wherein the display panel comprises:
subpixels located in the display area; and
a shift register comprising a plurality of stages of shift units that is cascaded, each of the plurality of stages of shift units being electrically connected to one of control signal lines and at least one of the subpixels, and being configured to output a driving signal to the at least one of the subpixels in response to a control signal, wherein the shift register is located in the display area, and at least one control signal line of the control signal lines is located in the display area.
